(19) United States
(12) Patent Application Publication
(10) Pub. No.: US 2026/0333923 A1
(43) Pub. Date: Oct. 22, 2026

(54) PHOTOELECTRIC CONVERSION DEVICE AND EQUIPMENT

(71) Applicant: CANON KABUSHIKI KAISHA, Tokyo (JP)

(72) Inventor: HIROSHI SEKINE, Kanagawa (JP)

(21) Appl. No.: 19/634,364

(22) Filed: Mar. 31, 2026

(30) Foreign Application Priority Data
Apr. 17, 2025 (JP) 2025-068350

(51) Int. Cl. H10F 39/00; H10F 39/18

(52) U.S. Cl. CPC H10F 39/809; H10F 39/182; H10F 39/806; H10F 39/811

(57) ABSTRACT

A photoelectric conversion device constituted by stacking a first substrate where a pixel including an avalanche photodiode is arranged, and a second substrate where a signal processing circuit configured to process a signal from the pixel is arranged, is provided. The first and second substrates are joined by metal joints including first and second joints arranged adjacent to each other, the photodiode is connected to a first line supplying a first voltage and a second line supplying a second voltage, the first and second voltages are supplied from a side of the second substrate, the first joint is connected to an signal output node of the photodiode, the second joint is supplied with a fixed voltage, and the fixed voltage is a voltage between the first voltage and the second voltage or a voltage equal to the first voltage.

### BACKGROUND

### Field of the Technology

The present disclosure relates to a photoelectric conversion device and equipment.

### Description of the Related Art

There is known a photoelectric conversion element using an avalanche photodiode (APD) that causes avalanche multiplication capable of detecting faint light of a single photon level. Japanese Patent Laid-Open No. 2023-183169 describes a light detection element formed by stacking the first substrate where a pixel using an APD is arranged and the second substrate where a pixel circuit configured to process a signal output from the pixel is arranged. Japanese Patent Laid-Open No. 2023-183169 also describes that the first substrate and the second substrate are joined using joints between metal electrodes.

In a photoelectric conversion device in which substrates are stacked, improvement in joint strength between the stacked substrates can lead to improvement in reliability of the photoelectric conversion device.

### SUMMARY

Some embodiments of the present disclosure provide a technique advantageous in improving the reliability of a photoelectric conversion device.

According to some embodiments, a photoelectric conversion device constituted by stacking a first substrate where a pixel including an avalanche photodiode is arranged, and a second substrate where a signal processing circuit configured to process a signal output from the pixel is arranged, wherein the first substrate and the second substrate are joined by a plurality of metal joints including a first metal joint and a second metal joint arranged adjacent to each other, the avalanche photodiode is electrically connected to a first supply line supplied with a first voltage and a second supply line supplied with a second voltage, the first voltage and the second voltage are supplied from a side of the second substrate, the first metal joint is connected to an signal output node of the avalanche photodiode, the second metal joint is supplied with a fixed voltage, and the fixed voltage is a voltage between the first voltage and the second voltage or a voltage equal to the first voltage, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a view showing an arrangement example of a photoelectric conversion device according to an embodiment;

FIG. 2 is a view showing an arrangement example of the pixel array of the photoelectric conversion device shown in FIG. 1;

FIG. 3 is a block diagram showing an arrangement example of the photoelectric conversion device shown in FIG. 1;

FIG. 4 is a circuit diagram showing an arrangement example of the pixel of the photoelectric conversion device shown in FIG. 1;

FIGS. 5A and 5B are views for explaining an operation example of the pixel of the photoelectric conversion device shown in FIG. 1;

FIG. 6 is a sectional view showing an arrangement example of the pixels of the photoelectric conversion device shown in FIG. 1;

FIGS. 7A and 7B are plan views showing the arrangement example of the pixels shown in FIG. 6;

FIGS. 8A and 8B are plan views showing the arrangement example of the pixels shown in FIG. 6;

FIGS. 9A and 9B are a sectional view and a plan view, respectively, showing an arrangement example of the pixels of the photoelectric conversion device shown in FIG. 1;

FIG. 10 is a sectional view showing an arrangement example of the pixels of the photoelectric conversion device shown in FIG. 1;

FIGS. 11A and 11B are plan views showing the arrangement example of the pixels shown in FIG. 10;

FIGS. 12A and 12B are plan views showing the arrangement example of the pixels shown in FIG. 10;

FIGS. 13A and 13B are sectional views showing the arrangement example of the pixels shown in FIG. 10; and

FIG. 14 is a view showing an arrangement example of equipment incorporating the photoelectric conversion device according to the embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

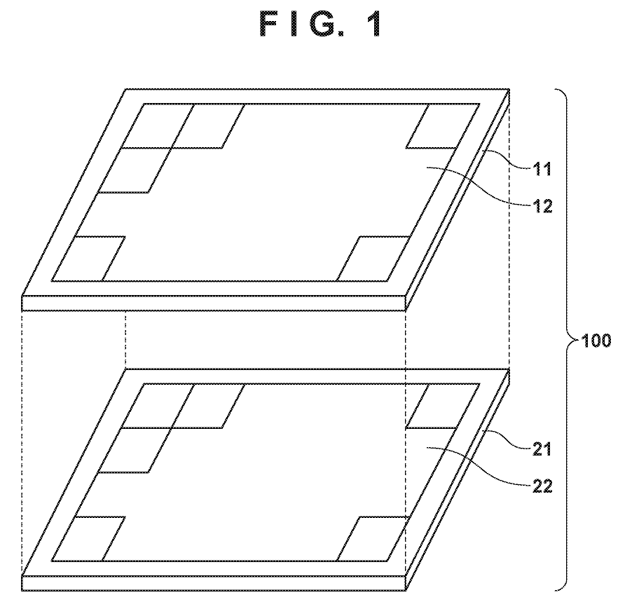

First, with reference to FIGS. 1-5B, an avalanche photodiode (to be sometimes referred to as an APD hereinafter) that can be used in a photoelectric conversion device 100 to be described below will be described. In the following embodiment, an electron is a signal carrier, and a single photon avalanche photodiode (to be sometimes referred to as a SPAD hereinafter) element that detects a change of the potential of the cathode of an APD caused by an avalanche current generated upon avalanche breakdown of the APD will be described. However, a hole may be the signal carrier, and a change of the potential of the anode of the APD may be detected. The photoelectric conversion element used in the photoelectric conversion device is not limited to the APD, and another type of photodiode such as a PN diode or a PIN diode may be used as the photoelectric conversion element.

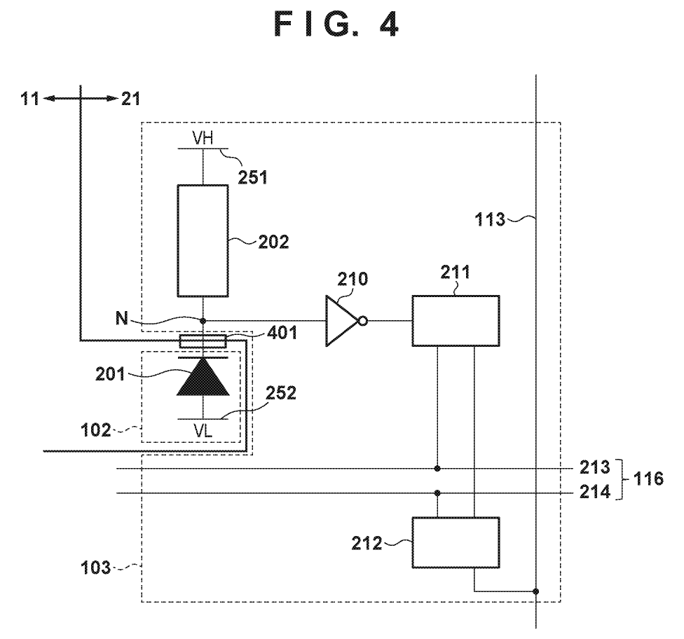

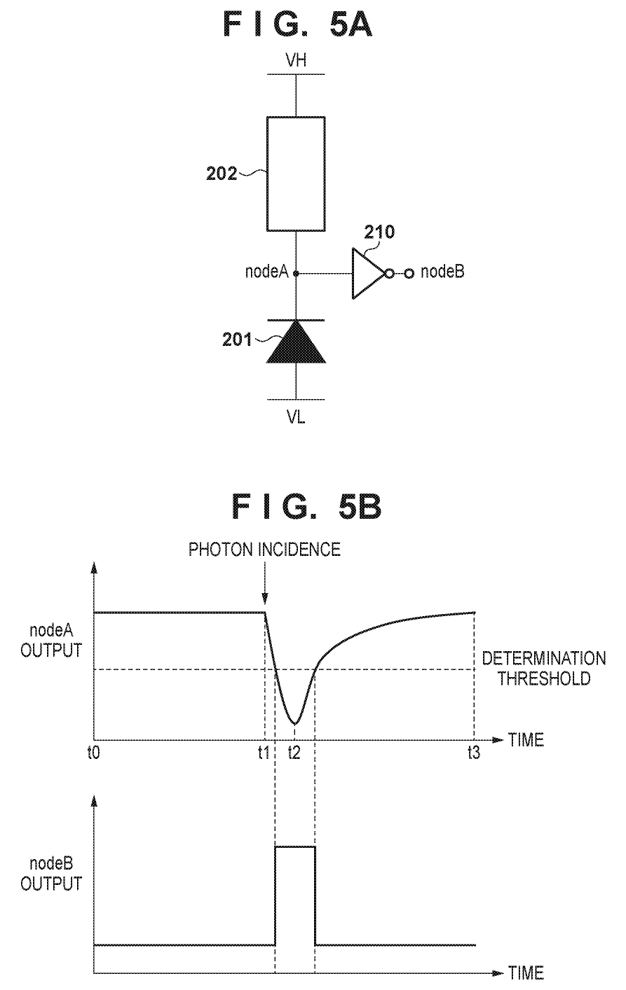

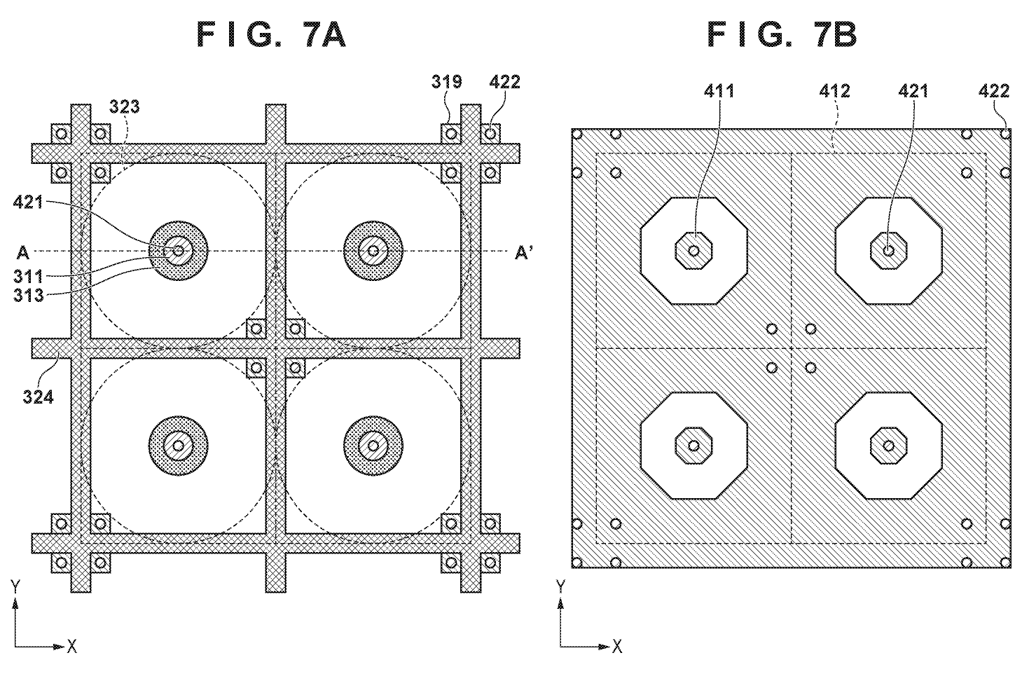

FIG. 1 is a view showing an arrangement example of the photoelectric conversion device 100. The photoelectric conversion device 100 can be constituted by stacking two substrates, that is, a sensor substrate 11 (to be sometimes simply referred to as a substrate 11 hereinafter) and a circuit substrate 21 (to be sometimes simply referred to as a substrate 21 hereinafter) and electrically connecting them. That is, the photoelectric conversion device 100 may be a stacked device. In the substrate 11 (first substrate), a semiconductor layer 301 in which a plurality of pixels 101 are arranged, and the like are arranged, which will be described later with reference to FIG. 6 and subsequent drawings. The substrate 11 includes a pixel region 12 where the plurality of pixels 101 each including an APD 201 are provided. The substrate 21 (second substrate) includes a circuit region 22 where signal processing circuits 103 (shown in FIGS. 3 and 4) that process signals output from the plurality of pixels 101 are arranged.

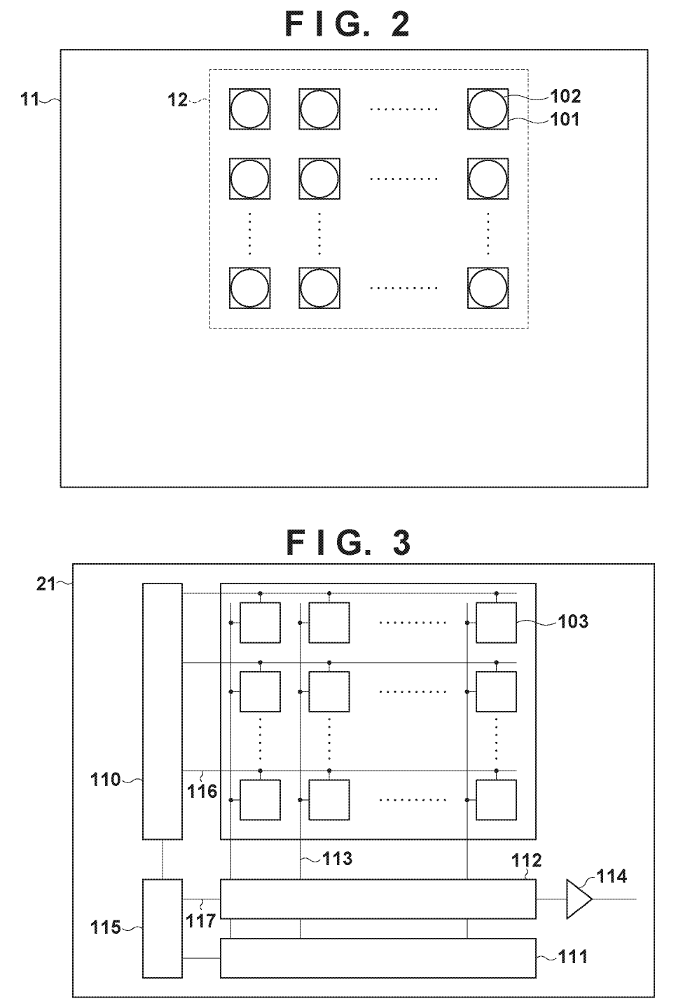

FIG. 2 is a view showing an arrangement example of the substrate 11. The pixels 101 each including a photoelectric conversion element 102, that includes an APD as a photodiode, are arranged in a two-dimensional array in an orthogonal projection to a main surface 391 of the semiconductor layer 301 (to be described with reference to FIG. 6 and subsequent drawings), forming the pixel region 12. The pixel 101 is typically a pixel for generating an image, but when it is used in a Time of Flight (ToF) distance measurement device or the like, it does not necessarily generate an image. That is, the pixel 101 may be configured to measure the time when light arrives and the quantity of light.

FIG. 3 is a block diagram showing an arrangement example of the substrate 21. The substrate 21 can include the signal processing circuits 103 that process charges photoelectrically converted by the photoelectric conversion elements 102 arranged in the pixels 101, a readout circuit 112, a control pulse generation circuit 115, a horizontal scanning circuit 111, signal lines 113, a vertical scanning circuit 110, and the like. The signal processing circuits 103 shown in FIG. 3 may be arranged so as to correspond to each pixel 101 shown in FIG. 2. In this case, the pixel 101 (photoelectric conversion element 102) and the signal processing circuit 103 can be electrically connected via a connection wiring provided for each pixel 101.

The vertical scanning circuit 110 receives a control pulse supplied from the control pulse generation circuit 115, and supplies a control pulse to the respective pixels 101 via driving lines 116. A logic circuit such as a shift register or an address decoder can be used for the vertical scanning circuit 110.

A signal output from the pixel 101 is processed by the signal processing circuit 103. A counter, a memory, and the like can be provided in the signal processing circuit 103. The memory can hold, as a digital value, a count value obtained by counting by the counter.

The horizontal scanning circuit 111 inputs, to the signal processing circuits 103, a control pulse for sequentially selecting respective columns in order to read out signals from the memories of the signal processing circuits 103 corresponding to the respective pixels 101 in which digital signals are held. As for a selected column, a signal is output to the signal line 113 from the signal processing circuit 103 corresponding to the pixel 101 selected by the vertical scanning circuit 110. The signal output to the signal line 113 is output via an output circuit 114 to a recording unit or a signal processing unit outside the photoelectric conversion device 100.

The array of the pixels 101 in the pixel region 12 shown in FIG. 2 is not limited to a two-dimensional array. The pixels 101 may be arranged one-dimensionally (in a line). The function of the signal processing circuit 103 need not always be provided one by one in all the pixels 101 (photoelectric conversion elements 102). For example, one signal processing circuit 103 may be shared by two or more pixels 101 (photoelectric conversion elements 102) to sequentially perform signal processing.

As shown in FIGS. 2 and 3, the signal processing circuits 103 can be arranged in a region overlapping the pixel region 12 in an orthogonal projection to the pixel region 12. The vertical scanning circuit 110, the horizontal scanning circuit 111, the readout circuit 112, the output circuit 114, the control pulse generation circuit 115, and the like can be so arranged as to overlap a gap between the end of the substrate 11 and the end of the pixel region 12. In other words, the substrate 11 has the pixel region 12 and a non-pixel region (peripheral region) arranged around the pixel region 12. In this case, the vertical scanning circuit 110, the horizontal scanning circuit 111, the readout circuit 112, the output circuit 114, and the control pulse generation circuit 115 can be arranged in a region overlapping the non-pixel region.

FIG. 4 shows an example of a block diagram including an equivalent circuit focusing on one pixel 101 (photoelectric conversion element 102). In the arrangement shown in FIG. 4, the photoelectric conversion element 102 including the APD 201 is provided in the semiconductor layer 301 of the substrate 11, and the remaining components are provided in the substrate 21.

The APD 201 generates a charge pair corresponding to incident light by photoelectric conversion. The APD 201 is arranged in a current path between a supply line 251 supplied with a voltage VH and a supply line 252 supplied with a voltage VL. That is, the APD 201 is electrically connected to the supply line 251 supplied with the voltage VH and the supply line 252 supplied with the voltage VL. The voltage VH is higher than the voltage VL. The anode of the APD 201 is connected to the supply line 252. The cathode of the APD 201 is connected to the supply line 251 via a quench element 202 and the like. A reverse bias voltage is supplied to the anode and the cathode so that the APD 201 performs an avalanche multiplication operation. In a state in which such a reverse bias voltage is supplied, charges generated by incident light cause avalanche multiplication, generating an avalanche current.

In a case where the reverse bias voltage is supplied to the APD 201, there are a Geiger mode in which the APD 201 is operated by a voltage difference between the anode and the cathode larger than a breakdown voltage, and a linear mode in which the APD 201 is operated by a voltage difference between the anode and the cathode equal to or smaller than the breakdown voltage. An APD operated in the Geiger mode is called a Single Photon Avalanche Diode (SPAD). For example, the voltage VL can be about -30 V, and the voltage VH can be about 1 V to 2 V. The APD 201 may be operated in the linear mode or the Geiger mode.

The quench element 202 is electrically connected between the APD 201 and the supply line 251 in the current path between the supply line 251 and the supply line 252. A metal joint 401 (first metal joint) for joining the substrate 11 and the substrate 21 (to be described later) is arranged between the quench element 202 and the APD 201, thereby electrically connecting the quench element 202 and the APD 201. The quench element 202 functions as a load circuit (quench circuit) at the time of signal multiplication by avalanche multiplication, and operates to suppress a voltage supplied to the APD 201 and suppress avalanche multiplication (quench operation). The quench element 202 also operates to return the voltage supplied to the APD 201 to a voltage (VH - VL) by supplying a current by an amount corresponding to a voltage drop caused by the quench operation (recharge operation).

In addition to the quench element 202, the signal processing circuit 103 can include a waveform shaping circuit 210, a counter circuit 211, and a selection circuit 212. In this embodiment, the signal processing circuit 103 suffices to include any of the waveform shaping circuit 210, the counter circuit 211, and the selection circuit 212.

The waveform shaping circuit 210 shapes a potential change of the cathode of the APD 201 that is obtained at the time of photon detection, and outputs a pulse signal. As the waveform shaping circuit 210, for example, an inverter circuit is used. In the arrangement shown in FIG. 4, the use of one inverter as the waveform shaping circuit 210 is exemplified. However, the present disclosure is not limited to this, and a circuit constituted by series-connecting a plurality of inverters may be used as the waveform shaping circuit 210, or another circuit having the waveform shaping effect may be used.

The counter circuit 211 counts pulse signals output from the waveform shaping circuit 210 and holds the count value. When a control pulse pRES is supplied from the vertical scanning circuit 110 shown in FIG. 3 via a driving line 213 corresponding to a part of the driving line 116 shown in FIG. 3, the signal held by the counter circuit 211 is reset.

The selection circuit 212 receives a control pulse pSEL from the vertical scanning circuit 110 via a driving line 214 corresponding to a part of the driving line 116 shown in FIG. 3, and switches electrical connection or disconnection between the counter circuit 211 and the signal line 113. The selection circuit 212 can include, for example, a buffer circuit for outputting a signal.

A switching element such as a transistor may be interposed between the quench element 202 and the APD 201 or between the photoelectric conversion element 102 and the signal processing circuit 103 so that electrical connection can be switched. Similarly, supply of the voltage VH or voltage VL to the photoelectric conversion element 102 may be electrically switchable using a switching element such as a transistor.

In this embodiment, the counter circuit 211 is arranged in the signal processing circuit 103. However, the present disclosure is not limited to this, and a Time-to-Digital Converter (TDC) and a memory may be used instead of the counter circuit 211 so that the photoelectric conversion device 100 obtains a pulse detection timing. In this case, the generation timing of a pulse signal output from the waveform shaping circuit 210 is converted into a digital signal by the TDC. The TDC receives a control pulse pREF (reference signal) from the vertical scanning circuit 110 via the driving line 116 for measurement of the timing of the pulse signal. By using the control pulse pREF as a reference, the TDC obtains, as a digital signal, a signal when the input timing of a signal output from each pixel 101 via the waveform shaping circuit 210 is regarded as a relative time.

In the arrangement shown in FIG. 4, the quench element 202, the waveform shaping circuit 210, the counter circuit 211, and the selection circuit 212 are arranged in one circuit substrate 21. However, the present disclosure is not limited to this. For example, the quench element 202 and the waveform shaping circuit 210 may be arranged in one substrate, the counter circuit 211 and the selection circuit 212 may be arranged in another substrate, and these substrates may be stacked.

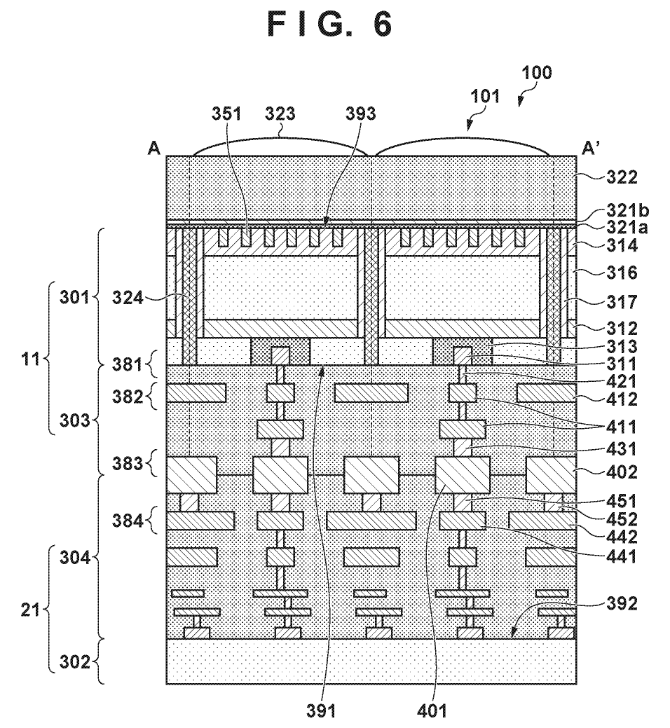

FIGS. 5A and 5B are views schematically showing the relationship between the operation of the APD 201 and an output signal. FIG. 5A is a view showing an excerpt of the APD 201, quench element 202, and waveform shaping circuit 210 shown in FIG. 4. Here, the input side of the waveform shaping circuit 210 is a node A and its output side is a node B. FIG. 5B shows waveform changes at the node A and the node B. The node A is located at the same position as a signal output node N of the APD 201 shown in FIG. 4.

From time t0 to time t1, a voltage of the voltage VH - the voltage VL is applied to the APD 201. When a photon enters the APD 201 at time t1, avalanche multiplication occurs in the APD 201, an avalanche multiplication current flows into the quench element 202, and the potential of the node A drops. When the voltage drop amount further increases and the voltage difference applied to the APD 201 decreases, the avalanche multiplication of the APD 201 stops as shown at time t2, and the potential level of the node A does not drop any more from a predetermined value. In a period between time t2 and time t3, a current compensating for the voltage drop from the voltage VL flows to the node A. At time t3, the node A is settled at the original potential level. A portion at which the output waveform exceeds a given threshold at the node A is waveform-shaped by the waveform shaping circuit 210 and output as a signal to the node B.

The arrangement of the signal lines 113, readout circuit 112, and output circuit 114 is not limited to the arrangement shown in FIG. 3. For example, each signal line 113 may be arranged to extend in the row direction (the longitudinal direction in FIG. 3), and the readout circuit 112 may be arranged at the end of the signal line 113.

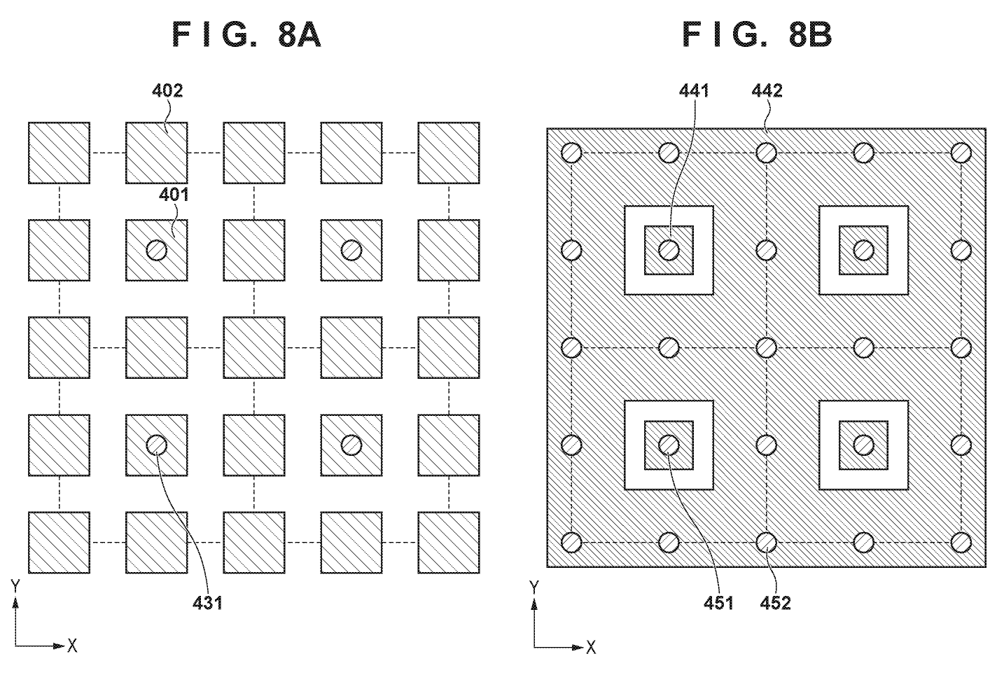

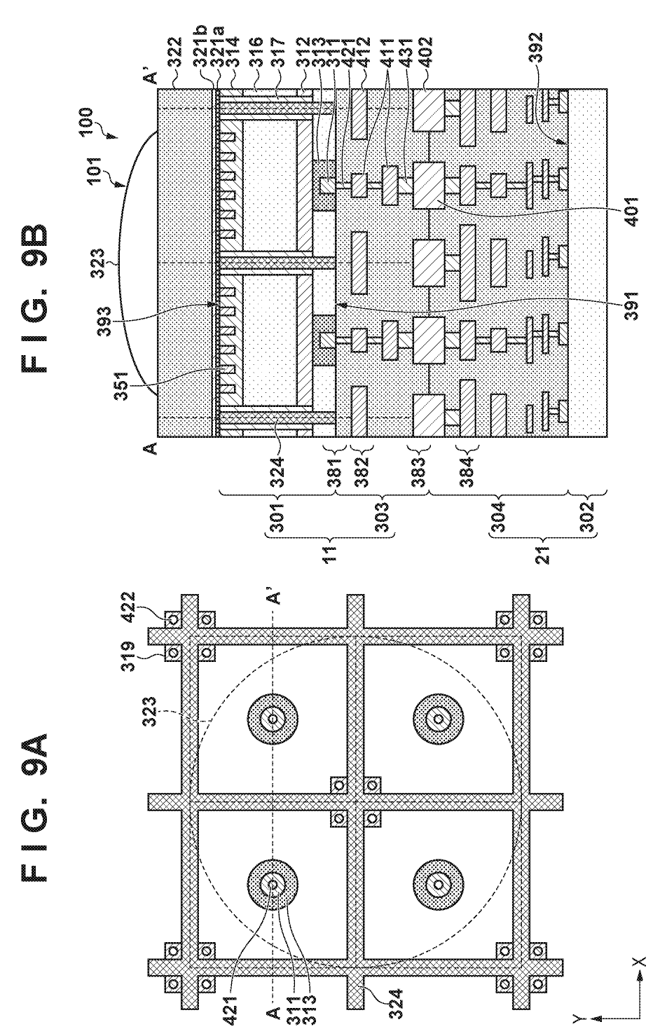

Next, the arrangement of the pixels 101 arranged in the photoelectric conversion device 100 according to this embodiment will be described in detail. FIG. 6 is a sectional view showing the arrangement of the pixels 101 arranged in the pixel region 12. FIGS. 7A-8B are plan views showing the arrangement of the pixels 101. FIG. 6 is a sectional view taken along a line A - A' shown in FIG. 7A. FIG. 7A is a plan view at the main surface 391 (position 381) of the semiconductor layer 301 shown in FIG. 6. FIG. 7B is a plan view at a position 382 focusing on wiring patterns 411 and 412 arranged in a wiring layer closest to the semiconductor layer 301 among the wiring patterns 411 and 412 arranged in a wiring structure 303 shown in FIG. 6. FIG. 8A is a plan view at a position 383 focusing on a plurality of metal joints 401 and 402 for joining the substrate 11 and the substrate 21 shown in FIG. 6. As shown in FIG. 8A, the plurality of metal joints 401 and 402 can be arranged in the X direction and the Y direction crossing the X direction to form a matrix. FIG. 8B is a plan view at a position 384 focusing on wiring patterns 441 and 442 arranged in a wiring layer closest to the substrate 11 among the wiring patterns 441 and 442 arranged in a wiring structure 304 shown in FIG. 6. As shown in FIG. 6, the substrate 11 includes the semiconductor layer 301 where the APDs 201 are arranged, and the wiring structure 303 arranged between the main surface 391 of the semiconductor layer 301 and the substrate 21 and including the plurality of wiring patterns 411 and 412 in a dielectric. The substrate 21 includes a semiconductor layer 302 where the signal processing circuits 103 are arranged, and the wiring structure 304 arranged between a main surface 392 of the semiconductor layer 302 and the substrate 11 and including the plurality of wiring patterns 441 and 442 in a dielectric. The photoelectric conversion device 100 shown in FIGS. 6-8B has a so-called back-illuminated type sensor configuration.

In the photoelectric conversion device 100, the plurality of pixels 101 are arranged in the substrate 11 including the semiconductor layer 301 formed of a semiconductor material. Each of the plurality of pixels 101 includes the APD 201 formed in the semiconductor layer 301. It can also be said that the semiconductor layer 301 having the main surface 391 and a main surface 393 includes the APD 201 as a photodiode. Each pixel 101 (APD 201) is isolated by an element isolation portion 324 extending from the main surface 391 of the semiconductor layer 301 toward the main surface 393 and arranged to electrically isolate the adjacent APDs 201 from each other. The photoelectric conversion device 100 further includes the semiconductor layer 302 of the substrate 21 arranged to face the main surface 391 of the semiconductor layer 301 (substrate 11). Elements such as transistors constituting the above-described signal processing circuits 103 and the like can be arranged in the semiconductor layer 302 of the substrate 21.

Each pixel 101 includes a semiconductor region 311, a semiconductor region 313, and a semiconductor region 316 of the same conductivity type. Each pixel 101 further includes a semiconductor region 312, a semiconductor region 314, a semiconductor region 317, and a semiconductor region 319 of a conductivity type opposite to the conductivity type of the semiconductor regions 311, 313, and 316. For example, the semiconductor regions 311, 313, and 316 may be n-type semiconductor regions, and the semiconductor regions 312, 314, 317, and 319 may be p-type semiconductor regions. An example of the semiconductor material used for the semiconductor layer 301 is silicon. Accordingly, each of the semiconductor regions 311, 312, 313, 314, 316, 317, and 319 can be a region obtained by doping an impurity corresponding to the conductivity type to silicon. For example, each of the semiconductor regions 311, 312, 313, 314, 317, and 319 may be formed in the n-type semiconductor layer 301 (semiconductor region 316) using an ion implantation method or the like.

In the arrangement shown in FIG. 6, light enters from the upper side of the drawing. That is, in the semiconductor layer 301, the main surface 393 is the light incident surface. The n-type semiconductor region 311 is arranged in the vicinity of the main surface 391 of the semiconductor layer 301, and the n-type semiconductor region 313 is arranged around the semiconductor region 311. The p-type semiconductor region 312 is arranged at a position where it overlaps the semiconductor region 311 and the semiconductor region 313 in an orthogonal projection to the main surface 391 of the semiconductor layer 301 of the substrate 11 (to be sometimes simply referred as a planar view with respect to the substrate 11). Hereinafter, the expression "the semiconductor regions overlap" indicates that the semiconductor regions overlap in a planar view with respect to the substrate 11. The expression "overlap" may also be used in other arrangements. The n-type semiconductor region 316 is further arranged at a position where it overlaps the semiconductor region 312.

The semiconductor region 311 is a region having a higher n-type impurity concentration than the semiconductor region 313 and the semiconductor region 316. A p-n junction portion is formed between the p-type semiconductor region 312 and the n-type semiconductor region 311. By setting the impurity concentration of the semiconductor region 312 lower than the impurity concentration of the semiconductor region 311, a reverse bias is applied and the whole region of the semiconductor region 312 overlapping the center of the semiconductor region 311 becomes a depletion layer region. In this case, the potential difference between the semiconductor region 311 and the semiconductor region 312 is larger than the potential difference between the semiconductor region 312 and the semiconductor region 316. Further, the depletion layer region extends to a partial region of the semiconductor region 311, and a strong electric field is induced in the depletion layer region. This strong electric field induces avalanche multiplication in the depletion layer region extending to the partial region of the semiconductor region 311, and a current based on the multiplied charges is output as a signal charge. When the light having entered the pixel 101 is photoelectrically converted and avalanche multiplication is induced in the depletion layer region (avalanche multiplication region), the generated n-type charges are collected in the semiconductor region 311.

The semiconductor region 311 is electrically connected to the wiring pattern 411 arranged in the wiring structure 303 via a conductive plug 421 contacting the semiconductor region 311. The wiring pattern 411 and the metal joint 401 for joining the substrate 11 and the substrate 21 are electrically connected by a conductive via 431. Furthermore, the metal joint 401 is electrically connected to a transistor or the like constituting the signal processing circuit 103 arranged in the semiconductor layer 302 via the wiring patterns 441 and conductive vias 451 arranged in the wiring structure 304. The semiconductor region 311 is the cathode of the APD 201 shown in FIG. 4. The semiconductor region 311 is connected to the signal processing circuit 103 via the metal joint 401 connected to the signal output node N of the APD 201, and is further connected to the supply line 251.

The semiconductor region 312 is connected to the wiring pattern 412 via the semiconductor region 317, and the semiconductor region 319 and a conductive plug 422 shown in FIG. 7A. By setting the impurity concentration of the semiconductor region 319 higher than the impurity concentration of the semiconductor region 317, the contact resistance between the semiconductor region 319 and the conductive plug 422 is reduced. The semiconductor region 312 is the anode of the APD 201 shown in FIG. 4, and is connected to the supply line 252 via the semiconductor regions 317 and 319 and the wiring pattern 412. The current path between the semiconductor region 312 and the supply line 252 may be arranged in the substrate 11 and not arranged in the substrate 21, as shown in FIG. 4. In other words, the plurality of wiring patterns 441 and 442 arranged in the wiring structure 304 of the substrate 21 shown in FIG. 6 may not include the wiring pattern connected to the supply line 252. However, the present disclosure is not limited to this, and the voltage VL may be supplied from the supply line 252 via the wiring pattern arranged in the substrate 21.

In FIG. 6, the semiconductor region 313 may be not the n-type semiconductor region but a p-type semiconductor region. In this case, the impurity concentration of the semiconductor region 313 is set lower than the impurity concentration of the semiconductor region 312. If the impurity concentration of the semiconductor region 313 is too high, an avalanche multiplication region is generated between the semiconductor region 313 and the semiconductor region 311, and the Dark Count Rate (DCR) may increase.

As described above, each pixel 101 (APD 201) is isolated by the element isolation portion 324. In the element isolation portion 324, an insulator is embedded. The insulator may be fully embedded in the element isolation portion 324, or may have some voids. For the insulator, a material such as silicon oxide, silicon nitride, or silicon oxynitride may be used. The insulator may be formed from one material, or may have a multi-layered structure using multiple materials.

In the arrangement shown in FIG. 6, a functional layer 321 including a pinning layer 321a, a planarizing layer 322, and microlenses 323 are arranged on the main surface 393 of the semiconductor layer 301. When the pinning layer 321a is arranged in contact with the main surface 393 of the semiconductor layer 301, holes are induced in the vicinity of the main surface 393 of the semiconductor layer 301, and a dark current is suppressed. For the pinning layer 321a, hafnium oxide, zirconium oxide, aluminum oxide, titanium oxide, tantalum oxide, or the like can be used. The functional layer 321 may have a single layer structure using one of these materials, or may have a layered structure using multiple materials. In other words, as shown in FIG. 6, the functional layer 321 may have a layered structure including an additional layer 321b stacked on the pinning layer 321a, and function as an anti-reflection layer. In this manner, the functional layer 321 can have a function of suppressing a dark current, an anti-reflection function, and the like.

The planarizing layer 322 arranged between the functional layer 321 and the microlenses 323 is a layer for planarizing the surface on which the microlenses 323 are arranged. If the functional layer 321 achieves the desired planarization, the planarizing layer 322 may be omitted. The microlens 323 can be formed using a resin material or the like. A color filter may be arranged between the functional layer 321 and the planarizing layer 322, or between the planarizing layer 322 and the microlens 323. Alternatively, the functional layer 321 or the planarizing layer 322 may function as a color filter.

As shown in FIG. 6, a plurality of trenches 351 may be provided in the main surface 393 (semiconductor region 314) of the semiconductor layer 301. The plurality of trenches 351 constitute a scattering diffraction structure arranged to at least partially overlap the APD 201 serving as the photodiode. The trench 351 can be embedded with a material having a refractive index different from the refractive index of the semiconductor layer 301 (semiconductor region 314). The material embedded in the trench 351 may be fully embedded in the trench 351, or may have some voids. As the material embedded in the trench 351, silicon oxide or silicon nitride may be used, an organic material such as a resin may be used, or a metal may be used. Alternatively, for example, the trench 351 may be an air gap. The trench 351 can be formed to have, for example, a depth of about 20 nm to 200 nm from the main surface 393 of the semiconductor layer 301.

The trench 351 constituting the scattering diffraction structure is arranged to at least partially overlap the APD 201, and light entering the pixel 101 is scattered by the scattering diffraction structure. This causes the incident light to travel obliquely in the pixel 101, so that the optical path length larger than the thickness of the semiconductor layer 301 can be ensured, and the photoelectric conversion efficiency increases. Further, since the optical path length increases, it is possible to photoelectrically convert light of a longer wavelength than in a case where the scattering diffraction structure is not provided. In order to achieve sufficiently high diffraction of light having entered the pixel 101, the depth of the trench 351 constituting the scattering diffraction structure may be larger than the width of the trench 351. For example, the depth of the trench 351 may be about 200 nm, and the width of the trench 351 may be about 100 nm to 150 nm. The trenches 351 can be formed in, for example, a grid in a planar view with respect to the substrate 11.

Next, the metal joint for joining the substrate 11 and the substrate 21 will be described. As described above, in the photoelectric conversion device 100, the metal joint 401 is arranged, which forms the signal path between the APD 201 and the signal processing circuit 103 and joins the substrate 11 and the substrate 21. The metal joint 401 is formed when a metal pattern arranged in the surface of the wiring structure 303 facing the substrate 21 of the wiring structure 303 and a metal pattern arranged in the surface of the wiring structure 304 facing the substrate 11 contact each other. For example, the metal joint 401 is a joint portion such as a Cu-Cu joint. Such the metal joint 401 is arranged for each pixel 101 to join the substrate 11 and the substrate 21. Here, it is conceivable to improve the joint strength between the substrate 11 and the substrate 21, thereby improving the reliability of the photoelectric conversion device 100. To achieve this, as shown in FIG. 6, in addition to the metal joint 401 forming the signal path between the APD 201 and the signal processing circuit 103, the metal joint 402 (second metal joint) is arranged in this embodiment. As shown in FIG. 6, the metal joint 402 can be a joint portion not connected to the APD 201 of any pixel 101 of the plurality of pixels 101. The metal joint 402 can be called a dummy joint portion that does not form the signal path between the APD 201 and the signal processing circuit 103 but is arranged to improve the joint strength between the substrate 11 and the substrate 21.

In this manner, as the metal joints for joining the substrate 11 and the substrate 21, the metal joint 401 connected to the signal output node of the APD 201 and the metal joint 402 not connected to the APD 201 are arranged. As shown in FIG. 8A, this improves the density of the metal joints 401 and 402, so that the joint strength between the substrate 11 and the substrate 21 can be improved. As a result, the reliability of the photoelectric conversion device 100 can be improved.

On the other hand, the metal joint 402 not connected to the APD 201 may influence the metal joint 401 connected to the signal output node of the APD 201. The voltage VL supplied from the supply line 252 to the anode (semiconductor region 312) of the APD 201 need not be supplied individually to the APD 201 arranged in each pixel 101. Hence, as shown in FIG. 7B, the wiring pattern 412 connected to the supply line 252 and used to supply the voltage VL can be shared by the APDs 201 arranged in the plurality of pixels 101. The plurality of wiring patterns 411, each of which connects the metal joint 401 corresponding to each pixel 101 and the cathode (semiconductor region 311) of the APD 201, are arranged in a plurality of spaces where the wiring pattern 412 is not arranged in the same wiring layer as the integrally formed wiring pattern 412. In this case, as shown in FIG. 6, the metal joint 402 is arranged to overlap the wiring pattern 412 connected to the supply line 252 for supplying the voltage VL in an orthogonal projection to the semiconductor layer 301. When the metal joint 402 is in an electrically floating state, the voltage of the metal joint 402 may be influenced by the voltage VL applied to the wiring pattern 412. On the other hand, as shown in FIG. 4, the metal joint 401 is applied with the voltage VH. Hence, a large voltage difference may be generated between the metal joint 401 and the metal joint 402 arranged adjacent to each other. In that case, for example, it needs to consider the breakdown voltage of the dielectric constituting each of the wiring structures 303 and 304 arranged between the metal joint 401 and the metal joint 402 adjacent to each other. In other words, it needs to consider the dielectric breakdown of the dielectric caused by the voltage difference between the metal joint 401 and the metal joint 402. Furthermore, for example, a signal output from the APD 201 and passing through the metal joint 401 may be influenced.

Therefore, in this embodiment, the metal joint 402 is supplied with a predetermined fixed voltage. Here, the fixed voltage is a voltage between the voltage VH (first voltage) and the voltage VL (second voltage), or a voltage equal to the voltage VH. This can suppress the voltage difference between the metal joint 401 and the metal joint 402. As describe above, the metal joint 402 may be supplied with, as the fixed voltage, the voltage equal to the voltage VH. Alternatively, for example, the metal joint 402 may be supplied with, as the fixed voltage, a voltage at a ground level serving as a reference for the voltage VH and the voltage VL. In other words, the metal joint 402 may be supplied with 0 V. Furthermore, for example, the metal joint 402 may be supplied with, as the fixed voltage, a voltage higher than the midpoint (1/2) between the voltage VH and the voltage VL and close to the voltage VH. Alternatively, for example, the voltage range between the voltage VH and the voltage VL is equally divided into three to ten ranges, and a voltage within the range closest to the voltage VH may be used as the fixed voltage. The value of the fixed voltage may be appropriately set in accordance with the sizes of the metal joints 401 and 402, the distance between the metal joint 401 and the metal joint 402, the material characteristics of the dielectrics constituting the wiring structures 303 and 304 arranged between the metal joint 401 and the metal joint 402, and the like.

When the fixed voltage is supplied to the metal joint 402, the metal joint 402 has a voltage closer to the voltage of the metal joint 401 than in the floating state. In this case, a large voltage difference may be generated between the metal joint 402 and the wiring pattern 412 arranged to cover the metal joint 402. As shown in FIG. 6, the wiring structure 303 of the substrate 11 can be configured to include the plurality of wiring layers each including wiring patterns. In that case, it may be configured such that the wiring pattern 412 connected to the supply line 252 among the plurality of wiring patterns 411 and 412 is not arranged in the wiring layer closest to the substrate 21 among the plurality of wiring layers. In the arrangement shown in FIG. 6, two wiring layers are arranged in the wiring structure 303. In the wiring layer close to the semiconductor layer 301, the wiring pattern 411 which constitutes the signal output node of the APD 201 together with the metal joint 401, and the wiring pattern 412 connected to the supply line 252 and applied with the voltage VL are arranged. On the other hand, in the wiring layer close to the substrate 21, the wiring pattern 411 is arranged but the wiring pattern 412 is not arranged. This decreases the electric field between the metal joint 402 and the wiring pattern 412, thereby reducing the influence on the breakdown voltage characteristic of the dielectric arranged between the metal joint 402 and the wiring pattern 412. The number of the wiring layers arranged in the wiring structure 303 is not limited to two, and may be appropriately set in accordance with the characteristics required for the photoelectric conversion device 100.

Alternatively, for example, the distance between the metal joint 401 and the metal joint 402 adjacent to each other may be shorter than the distance between the metal joint 402 and the wiring pattern 412 connected to the supply line 252 and closest to the metal joint 402. That is, the distance between the wiring pattern 412 and the metal joint 402 where a higher voltage is applied may be longer than the distance between the metal joint 402 and the metal joint 401 where a low voltage is applied. This can further improve the reliability of the photoelectric conversion device 100 arranged with the metal joints 402 to improve the joint strength.

As shown in FIG. 6, the metal joint 402 is supplied with the fixed voltage via a conductive via 452 from a predetermined wiring pattern 442 among the plurality of wiring patterns 441 and 442 arranged in the wiring structure 304 constituting the substrate 21. The plurality of wiring layers each including wiring patterns can be arranged in the wiring structure 304. In the arrangement shown in FIG. 6, the wiring structure 304 includes four wiring layers. FIG. 8B shows the wiring patterns in the wiring layer where the wiring pattern 442 in contact with the conductive via 452 contacting the metal joint 402 is arranged. The fixed voltage supplied to the metal joint 402 need not be supplied individually to each metal joint 402. Hence, as shown in FIG. 8B, the wiring pattern 442 for supplying the fixed voltage may be shared by the plurality of metal joints 402. The plurality of wiring patterns 441, each of which constitutes the signal output node N of the APD 201 arranged in each pixel 101, can be arranged in a plurality of spaces where the wiring pattern 442 is not arranged in the same wiring layer as the integrally formed wiring pattern 442. Here, the number of wiring layers arranged in the wiring structure 304 is not limited to four, and may be appropriately set in accordance with the characteristics required for the photoelectric conversion device 100.

A large voltage difference may be generated between the wiring pattern for supplying the fixed voltage to the metal joint 402 and the wiring pattern 412 connected to the supply line 252 and used to supply the voltage VL. Therefore, as shown in FIG. 6, the plurality of wiring patterns arranged in the wiring structure 303 constituting the substrate 11 may not include the wiring pattern connected to the metal joint 402. It can also be said that the plurality of wiring patterns arranged in the wiring structure 303 may not include the wiring pattern for supplying the fixed voltage.

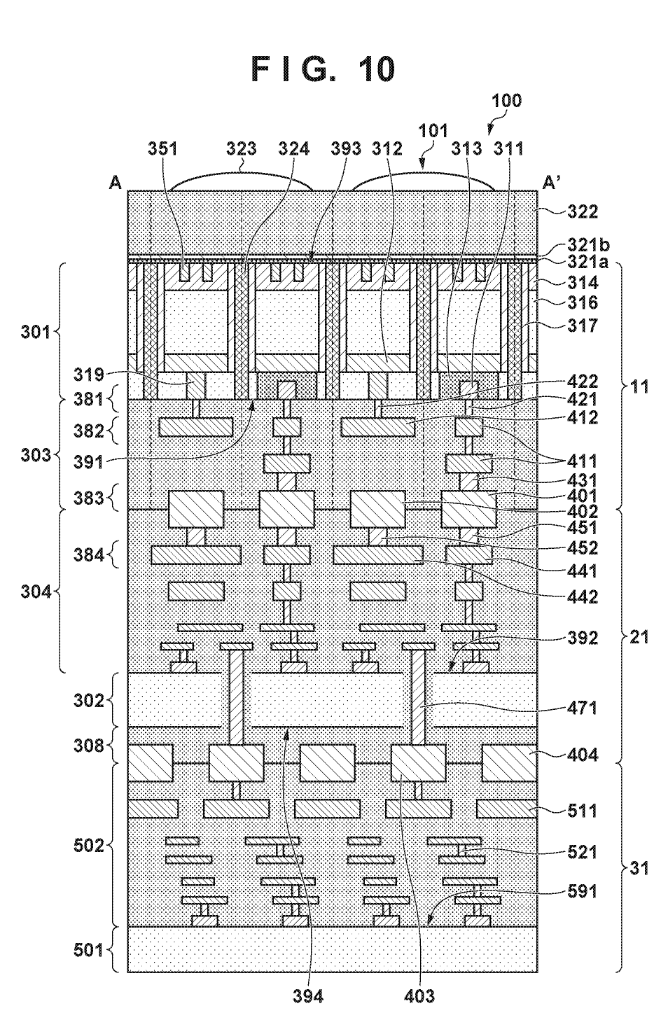

In the arrangement shown in FIGS. 6-8B, one microlens 323 is arranged to correspond to one pixel 101. However, the present disclosure is not limited to this. For example, as shown in FIGS. 9A and 9B, the microlens 323 may be shared by the plurality of pixels 101. For example, as in a plan view shown in FIG. 9A, four pixels 101 arranged in the X direction and the Y direction crossing the X direction to form a 2 × 2 matrix may share one microlens 323. This can implement, for example, image plane phase difference autofocus (AF) in the photoelectric conversion device 100. Even in such a case, as shown in the sectional view of FIG. 9B, as the metal joints for joining the substrate 11 and the substrate 21, the metal joint 401 connected to the signal output node N of the APD 201 and the metal joint 402 for improving the joint strength are arranged. In this case, the metal joint 402 is supplied with the fixed voltage. This can improve the reliability of the photoelectric conversion device 100.

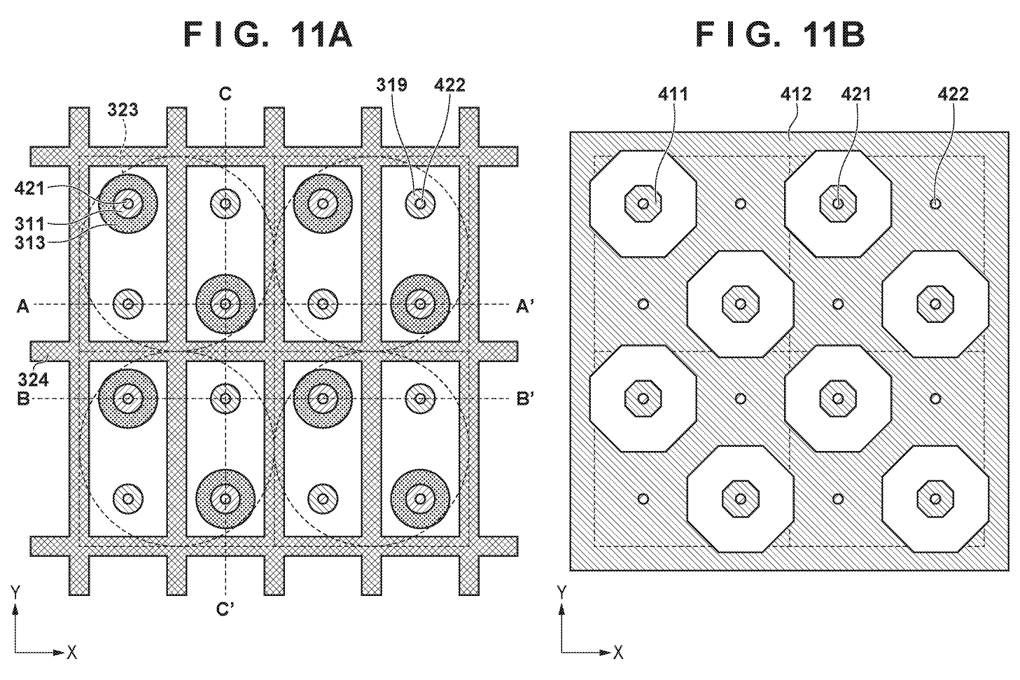

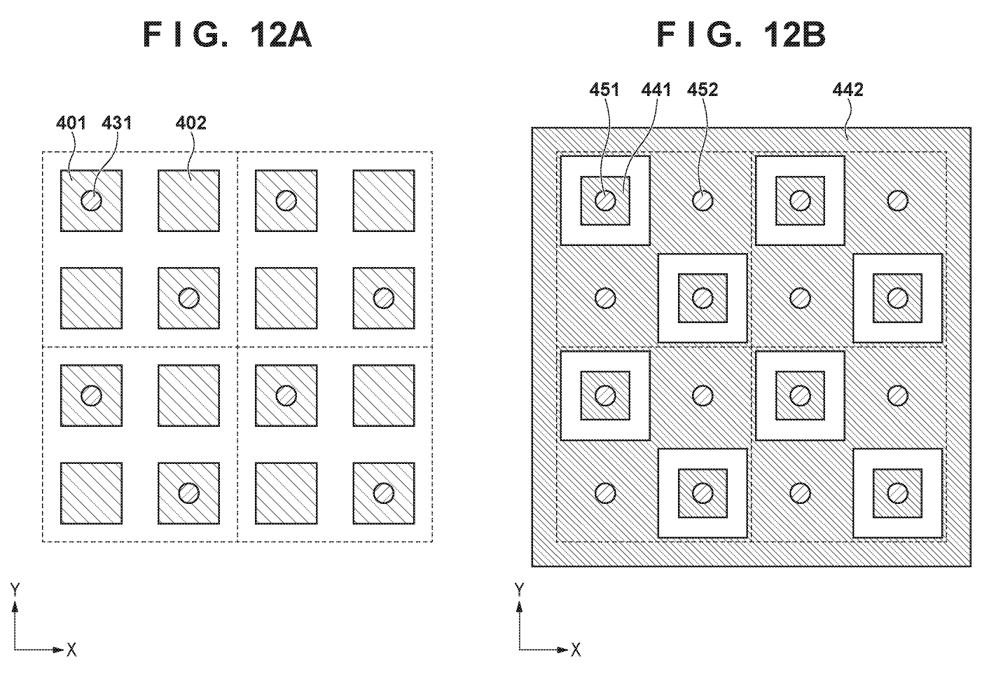

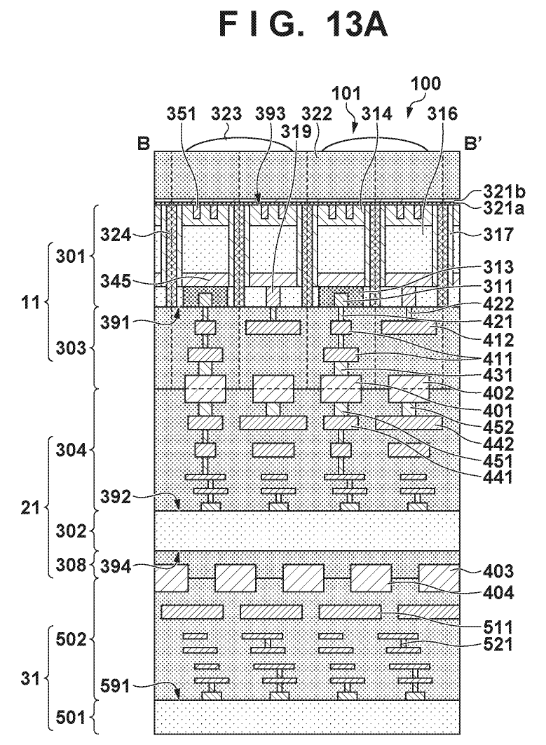

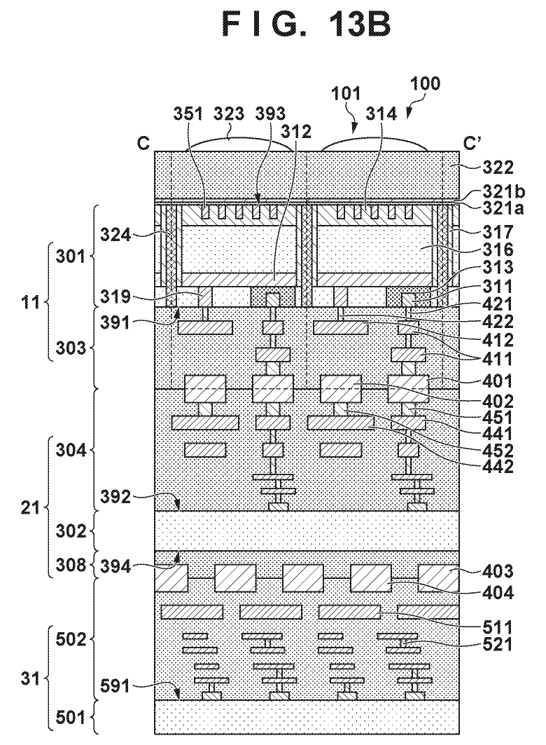

FIGS. 10-13B are views showing another arrangement example of the photoelectric conversion device 100 that has image plane phase difference AF. FIG. 10 is a sectional view showing the arrangement of the pixels 101. FIGS. 11A-12B are plan views showing the arrangement of the pixels 101. FIG. 10 is a sectional view taken along a line A - A' shown in FIG. 11A. FIG. 11A is a plan view at the main surface 391 (position 381) of the semiconductor layer 301 shown in FIG. 10. FIG. 11B is a plan view at the position 382 focusing on the wiring patterns 411 and 412 arranged in the wiring layer closest to the semiconductor layer 301 among the wiring patterns 411 and 412 arranged in the wiring structure 303 shown in FIG. 10. FIG. 12A is a plan view at the position 383 focusing on the plurality of metal joints 401 and 402 for joining the substrate 11 and the substrate 21 shown in FIG. 10. FIG. 12B is a plan view at the position 384 focusing on the wiring patterns 441 and 442 arranged in the wiring layer closest to the substrate 11 among the wiring patterns 441 and 442 arranged in the wiring structure 304 shown in FIG. 10. FIGS. 13A and 13B are sectional views taken along a line B - B' and a line C - C' shown in FIG. 11A, respectively.

As shown in FIG. 11A, in a planar view with respect to the substrate 11, rectangular pixels 101 each having long sides in the X direction are arranged. Among the rectangular pixels 101, two pixels 101 adjacent to each other in the Y direction share the microlens 323. This implements image plane phase difference AF in the photoelectric conversion device 100. Two pixels 101 sharing the microlens 323 constitute one pixel group having an approximately square shape.

Similar to the arrangement shown in FIGS. 6 and 9A, in the arrangement shown in FIG. 10 as well, the metal joint 401 connected to the signal output node N of the APD 201 is arranged to overlap the cathode (semiconductor region 311) of the APD 201. More specifically, the wiring patterns arranged in the wiring structure 303 include the plurality of wiring patterns 411 each connecting one of the metal joints 401 and the APD 201 arranged in the corresponding pixel 101 so as to correspond to each of the plurality of metal joints 401. The metal joint 401 is arranged to overlap the conductive plug 421 connecting the corresponding wiring pattern 411 among the plurality of wiring patterns 411 and the APD 201 arranged in the corresponding pixel 101 among the plurality of pixels 101. The conductive plug 421 is a conductive plug contacting the cathode (semiconductor region 311) of the APD 201.

In the arrangement shown in FIG. 10, the metal joint 402 supplied with the fixed voltage is arranged to overlap the semiconductor region 319 for supplying the voltage VL to the anode (semiconductor region 312) of the APD 201. More specifically, the wiring patterns arranged in the wiring structure 303 include the wiring pattern 412 connected to the supply line 252 and shared by the APDs 201 arranged in the plurality of pixels 101. The metal joint 402 is arranged to overlap the conductive plug 422 connecting the wiring pattern 412 and the APD 201 arranged in the corresponding pixel 101 among the plurality of pixels 101. The conductive plug 422 is a conductive plug contacting the semiconductor region 319 of the APD 201 to supply the voltage VL to the anode (semiconductor region 312) of the APD 201. In the arrangement shown in FIGS. 6 and 9A, some metal joints 402 are arranged to overlap the conductive plugs 422, and the remaining metal joints 402 do not overlap the conductive plugs 422 as shown in FIGS. 6 and 9A. On the other hand, in the arrangement shown in FIG. 10, all the metal joints 402 can be arranged to overlap the conductive plugs 422.

As shown in FIGS. 10-13B, one metal joint 401 and one metal joint 402 may be arranged to overlap one pixel 101. The metal joint 401 and the metal joint 402 arranged to overlap one pixel 101 may be arranged along the X direction in a planar view with respect to the substrate 11. In this case, as shown in FIG. 12A, the metal joints 401 and 402 can be arranged at equal intervals along the X direction, which is the long-side direction of the pixel 101, and the Y direction, which is the short-side direction thereof. As a result, the joint strength for joining the substrate 11 and the substrate 21 becomes more uniform in a plane, and the reliability of joint between the substrate 11 and the substrate 21 can be improved.

As shown in FIG. 11A, regarding two pixels 101 sharing the microlens 323, the arrangement of the conductive plug 421 connected to the cathode (semiconductor region 311) of the APD 201 and the conductive plug 422 connected to the anode (semiconductor region 312) via the semiconductor region 319 may be reversed in the X direction. As a result, regarding the metal joints 401 and 402 arranged to overlap two pixels 101 sharing the microlens 323, the metal joints 401 and 402 are arranged side by side in the Y direction as shown in FIG. 12A. Furthermore, as shown in FIG. 11A, the conductive plugs 421 and 422 may be arranged alternately in the X direction and the Y direction. As a result, as shown in FIG. 12A, the metal joints 401 and 402 may be arranged alternately in the X direction and the Y direction.

Consider a case where, in each pixel 101, the conductive plug 421 is arranged on the upper side in the X direction in FIG. 11A, and the conductive plug 422 is arranged on the lower side in the X direction, so that the conductive plugs 421 and 422 are arranged side by side in the Y direction of the pixel 101. In this case, spaces for arranging the wiring patterns 411 shown in FIG. 11B, which are provided in the wiring pattern 412, may be continuous in the Y direction. That is, the connection of the wiring pattern 412 in the Y direction may be provided only in the end portion in the X direction. On the other hand, if the conductive plugs 421 and 422 are arranged alternately in the X direction and the Y direction as described above, the wiring pattern 412 can be connected in the X direction and the Y direction in a mesh pattern as shown in FIG. 11B. This can suppress generation of the in-plane distribution of the voltage VL supplied commonly to the APDs 201 arranged in the respective pixels 101.

Similar to the arrangement shown in FIG. 8B, the wiring pattern 442 for supplying the fixed voltage to the metal joint 402 may be shared by the plurality of metal joints 402 as shown in FIG. 12B. The plurality of wiring patterns 441, each of which forms the signal output node N of the APD 201 arranged in each pixel 101, are arranged in a plurality of spaces where the wiring pattern 442 is not arranged in the same wiring layer as the integrally formed wiring pattern 442. In this case, the wiring pattern 442 may be connected in the X direction and the Y direction in a mesh pattern.

As shown in FIGS. 10, 13A, and 13B, the photoelectric conversion device 100 may have a three-layered structure including a substrate 31 in addition to the substrates 11 and 21. In this case, the substrate 21 and the substrate 31 may be joined by a plurality of metal joints 403 and 404. Each of the metal joints 403 and 404 is a joint portion such as a Cu-Cu joint formed when a metal pattern arranged in the surface of a wiring structure 308 facing the substrate 31 of the wiring structure 308 and a metal pattern arranged in the surface of a wiring structure 502 facing the substrate 21 contact each other. For example, the quench element 202, the waveform shaping circuit 210, and the like of the signal processing circuit 103 are arranged in the semiconductor layer 302 constituting the substrate 21. The counter circuit 211, the selection circuit 212, and the like of the signal processing circuit 103 may be arranged in a semiconductor layer 501 constituting the substrate 31.

The substrate 21 can include the wiring structure 308 arranged between the substrate 31 and a main surface 394 of the semiconductor layer 302 on the opposite side of the main surface 392. The substrate 31 can include the semiconductor layer 501 where elements such as transistors constituting the circuits as described above, and the wiring structure 502 arranged between a main surface 591 of the semiconductor layer 501 and the substrate 21. The wiring structure 502 can be configured to include a plurality of wiring layers each including wiring patterns 511. FIGS. 10, 13A, and 13B show the wiring structure 502 including five wiring layers, but the number of the wiring layers may be four or less, or may be six or more. The wiring patterns 511 respectively arranged in the wiring layers are connected via conductive vias 521. The substrate 21 and the substrate 31 can be electrically connected via through vias 471 extending through the semiconductor layer 302 of the substrate 21.

The metal joint 403 can be a joint portion contacting the through via 471, which is used to electrically connect the substrate 21 and the substrate 31. On the other hand, the metal joint 404 can be a dummy joint portion which is not used to electrically connect the substrate 21 and the substrate 31 but arranged to improve the joint strength between the substrate 21 and the substrate 31. Similar to the above-described metal joint 402 for improving the joint strength between the substrate 11 and the substrate 21, the metal joint 404 may be supplied with a predetermined fixed voltage. In accordance with the arrangements of the substrates 11, 21, and 31, the metal joint 404 may be a joint portion in an electrically floating state.

FIGS. 10, 13A, and 13B show the photoelectric conversion device 100 having a three-layered structure where the substrates 11, 21, and 31 are stacked, but the present disclosure is not limited to this. In accordance with the characteristics required for the photoelectric conversion device 100 and the like, four or more substrates may be stacked. Here, four or more substrates can also be rephrased as four or more semiconductor layers.

As described above, the plurality of metal joints 401 and 402 for joining the substrate 11 and the substrate 21 are arranged in the photoelectric conversion device 100. In that case, the fixed voltage is supplied to the metal joint 402 which is not connected to the signal output node N of the APD 201 but used to improve the joint strength between the substrate 11 and the substrate 21. This can improve not only the reliability of joint but also the reliability of operation such as the electric characteristics of the photoelectric conversion device 100.

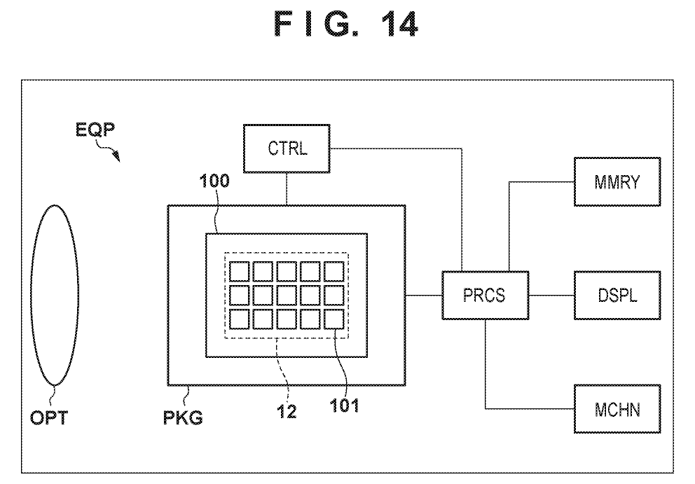

An application example of the photoelectric conversion device 100 according to the above-described embodiment will be described below. FIG. 14 is a schematic view of equipment EQP including the photoelectric conversion device 100. As shown in FIG. 14, the photoelectric conversion device 100 is stored in a semiconductor package PKG. The package PKG can include a base to which the photoelectric conversion device 100 is fixed, a lid member of glass or the like facing the photoelectric conversion device 100, and a conductive connecting member such as bonding wire or bump, which connects a terminal provided on the base and a terminal provided in the photoelectric conversion device 100. The equipment EQP may further include at least one of a control device CTRL, a processing device PRCS, a display device DSPL, and a memory device MMRY.

An optical system OPT forms an image on the pixel region 12 where the plurality of pixels 101 are arranged, and can be, for example, a lens, a shutter, a mirror, or the like. The control device CTRL controls the operation of the photoelectric conversion device 100 and can be, for example, a semiconductor device such as an ASIC. The processing device PRCS processes a signal output from the photoelectric conversion device 100 and can be a semiconductor device such as a CPU or an ASIC. The display device DSPL can be an EL display device or a liquid crystal display device that displays data obtained by the photoelectric conversion device 100. The memory device MMRY can be a magnetic device or a semiconductor device that stores data obtained by the photoelectric conversion device 100. The memory device MMRY can be a volatile memory such as an SRAM or a DRAM, or may be a nonvolatile memory such as a flash memory or a hard disk drive. A machine device MCHN can include a movable portion or a propulsion unit such as a motor or an engine. The machine device MCHN, for example, drives a component of the optical system OPT for a zooming, focusing, or shutter operation. In the equipment EQP, data output from the photoelectric conversion device 100 is displayed on the display device DSPL or transmitted to the outside by a communication device (not shown) provided in the equipment EQP. For this purpose, the equipment EQP may include the memory device MMRY or the processing device PRCS.

The equipment EQP incorporating the photoelectric conversion device 100 can also be applied to a surveillance camera, or an in-vehicle camera mounted in transport equipment such as an automobile, a railway vehicle, a ship, an aircraft, or an industrial robot. In addition, the equipment EQP incorporating the photoelectric conversion device 100 can be applied not only to transport equipment but also widely to equipment that uses object recognition such as an intelligent transport system (ITS).

According to the present disclosure, it is possible to provide a technique advantageous in improving the characteristics of a photoelectric conversion device.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-068350, filed Apr. 17, 2025, which is hereby incorporated by reference herein in its entirety.

What is claimed is:

1. A photoelectric conversion device constituted by stacking a first substrate where a pixel including an avalanche photodiode is arranged, and a second substrate where a signal processing circuit configured to process a signal output from the pixel is arranged, wherein
the first substrate and the second substrate are joined by a plurality of metal joints including a first metal joint and a second metal joint arranged adjacent to each other,
the avalanche photodiode is electrically connected to a first supply line supplied with a first voltage and a second supply line supplied with a second voltage,
the first voltage and the second voltage are supplied from a side of the second substrate,
the first metal joint is connected to an signal output node of the avalanche photodiode,
the second metal joint is supplied with a fixed voltage, and
the fixed voltage is a voltage between the first voltage and the second voltage or a voltage equal to the first voltage.

2. The device according to claim 1, wherein a voltage at a ground level serving as a reference for the first voltage and the second voltage is supplied as the fixed voltage.

3. The device according to claim 1, wherein
the first substrate includes a semiconductor layer where the avalanche photodiode is arranged, and a wiring structure arranged between a main surface of the semiconductor layer and the second substrate and including a plurality of wiring patterns in a dielectric, and
in a planar view, the second metal joint is arranged to overlap a wiring pattern connected to the second supply line among the plurality of wiring patterns.

4. The device according to claim 3, wherein
the wiring structure is configured to include a plurality of wiring layers, and
a wiring pattern connected to the second supply line among the plurality of wiring patterns is not arranged in a wiring layer closest to the second substrate among the plurality of wiring layers.

5. The device according to claim 3, wherein a distance between the first metal joint and the second metal joint is shorter than a distance between the second metal joint and a wiring pattern connected to the second supply line and closest to the second metal joint among the plurality of wiring patterns.

6. The device according to claim 3, wherein in a planar view, the second metal joint is arranged to overlap a conductive plug contacting the avalanche photodiode and connecting the avalanche photodiode and a wiring pattern connected to the second supply line among the plurality of wiring patterns.

7. The device according to claim 3, wherein the plurality of wiring patterns do not include a wiring pattern connected to the second metal joint.

8. The device according to claim 1, wherein
the second substrate includes a second semiconductor layer where the signal processing circuit is arranged, and a second wiring structure arranged between a main surface of the second semiconductor layer and the first substrate and including a plurality of second wiring patterns in a dielectric, and
the second metal joint is supplied with the fixed voltage via a predetermined second wiring pattern among the plurality of second wiring patterns.

9. The device according to claim 8, wherein the plurality of second wiring patterns do not include a wiring pattern connected to the second supply line.

10. The device according to claim 1, wherein
a quench element is electrically connected between the avalanche photodiode and the first supply line, and
the first metal joint electrically connects the quench element and the avalanche photodiode.

11. The device according to claim 1, wherein
a plurality of pixels including the pixel are arranged in the first substrate,
the plurality of pixels include a first pixel and a second pixel arranged adjacent to each other,
the first metal joint is connected to the signal output node of the avalanche photodiode arranged in the first pixel,
the plurality of metal joints include a third metal joint connected to the signal output node of the avalanche photodiode arranged in the second pixel, and a fourth metal joint supplied with the fixed voltage, and
in a planar view, the first metal joint and the second metal joint are arranged to overlap the avalanche photodiode arranged in the first pixel, and the third metal joint and the fourth metal joint are arranged to overlap the avalanche photodiode arranged in the second pixel.

12. The device according to claim 11, wherein
in a planar view,
the first pixel and the second pixel are arranged adjacent to each other in a first direction,
the first metal joint and the second metal joint are arranged side by side in a second direction crossing the first direction,
the third metal joint and the fourth metal joint are arranged side by side in the second direction,
the first metal joint and the fourth metal joint are arranged side by side in the first direction, and
the second metal joint and the third metal joint are arranged side by side in the first direction.

13. The device according to claim 11, wherein the first pixel and the second pixel share one microlens.

14. The device according to claim 1, wherein
a plurality of pixels including the pixel are arranged in the first substrate,
the plurality of metal joints are arranged in a first direction and a second direction crossing the first direction to form a matrix, and include a plurality of fifth metal joints including the first metal joint connected to the signal output node of the avalanche photodiode of a corresponding pixel among the plurality of pixels, and a plurality of sixth metal joints including the second metal joint supplied with the fixed voltage,
in a planar view, a fifth metal joint connected to the signal output node of the avalanche photodiode among the plurality of fifth metal joints, and one sixth metal joint among the plurality of sixth metal joints are arranged to overlap the avalanche photodiode arranged in each of the plurality of pixels, and
the plurality of fifth metal joints and the plurality of sixth metal joints are arranged alternately in the first direction and the second direction.

15. The device according to claim 14, wherein
the first substrate includes a semiconductor layer where the avalanche photodiode is arranged, and a wiring structure arranged between a main surface of the semiconductor layer and the second substrate and including a plurality of wiring patterns in a dielectric, and
the plurality of wiring patterns include a plurality of third wiring patterns each connecting one of the fifth metal joints and the avalanche photodiode arranged in a corresponding pixel so as to correspond to each of the plurality of fifth metal joints, and a fourth wiring pattern connected to the second supply line and shared by the avalanche photodiodes arranged in the plurality of pixels.

16. The device according to claim 15, wherein
each fifth metal joint is arranged to overlap a conductive plug contacting the avalanche photodiode and connecting a corresponding third wiring pattern among the plurality of third wiring patterns and the avalanche photodiode arranged in a corresponding pixel among the plurality of pixels, and
each sixth metal joint is arranged to overlap a conductive plug contacting the avalanche photodiode and connecting the fourth wiring pattern and the avalanche photodiode arranged in a corresponding pixel among the plurality of pixels.

17. The device according to claim 1, wherein
a plurality of pixels including the pixel are arranged in the first substrate, and
the second metal joint is not connected to the avalanche photodiode of any of the plurality of pixels.

18. The device according to claim 1, wherein the fixed voltage supplied to the second metal joint is supplied via a wiring pattern arranged in the second substrate.

19. Equipment comprising:
the photoelectric conversion device according to claim 1; and
a processing device configured to process a signal output from the photoelectric conversion device.
